(19) United States
(12) Patent Application Publication
(10) Pub. No.: US 2003/0077850 A1
(43) Pub. Date: Apr. 24, 2003

(54) Method for producing semiconductor fine particles

(76) Inventor: Takayasu Yamazaki, Minami-ashigara-shi (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/247,618

(22) Filed: Sep. 20, 2002

(30) Foreign Application Priority Data
Sep. 20, 2001 (JP) 287190/2001

(51) Int. Cl. H01L 21/00

(52) U.S. Cl. 438/48

(57) ABSTRACT

Disclosed is a method for producing semiconductor fine particles, which comprises a step of producing fine particles from particles consisting of at least two elements selected from Group II to Group VI elements in a fluid of a high-pressure jet. There is provided a novel simple and convenient method for producing semiconductor fine particles having uniform grain sizes.

### TECHNICAL FIELD

The present invention relates to a simple and convenient novel method for producing semiconductor fine particles having uniform grain sizes.

### RELATED ART

Remarkable progress has been made in the semiconductor industry to such an extent that almost no equipments or systems can exist without semiconductors at present. While silicon constitutes the mainstream of today's semiconductors, compound semiconductors have been noted in recent years due to the needs of higher processing speed and so forth. In the field of optoelectronics, for example, compound semiconductors play a leading role, and most of studies about light-emitting devices, photoelectric conversion elements, various lasers, nonlinear optical devices and so forth concern compound semiconductors. For example, Group II-VI compounds, which consist of a combination of a Group II element such as Zn and Cd and a Group VI element such as O and S, are known to have an excellent luminescence (fluorescence) property, and applications thereof to various fields are expected.

Meanwhile, these materials are generally used as particles having uniform grain sizes in order to more effectively obtain their performances. Moreover, in recent years, the need for material development based on nanotechnology has been strongly recognized, and even finer and more uniform sizes of particles of the aforementioned materials are also desired. The term “nanotechnology” used herein means techniques of manipulating and regulating atoms and molecules in the micro world in a scale of one millionth millimeter to utilize substance characteristics unique to nanosize substances (e.g., quantum effect) and thereby obtain their novel functions and excellent performances. The nanotechnology is not only important as a research field in itself, but also important in applied research fields of, for example, light-emitting devices, photoelectric conversion elements, various lasers, nonlinear optical devices and so forth. It is considered that a major part of conventional production and processing techniques will shift to nanotechnology techniques within the 21st century. Under such circumstances, there are a large number of references concerning synthesis methods of nanosize semiconductor particles and examples of their applications. For example, nanosize semiconductor particles can be synthesized by a precipitation method based on mixing of solutions, a particle growing method based on particle surface capping or the like. However, only polydisperse particles can be obtained in a usual precipitation method, for example. Further, although monodisperse particles can be obtained by the surface capping method using fractionation of particles, complicated experimental procedures and long-time work cannot be avoided. Therefore, a simple and convenient method that can overcome these problems is being desired.

### SUMMARY OF THE INVENTION

An object of the present invention is to provide a novel method for producing a dispersion of semiconductor fine particles having uniform grain sizes, in particular, a method for producing a dispersion of Group II-VI semiconductor particles having uniform grain sizes.

In order to achieve the aforementioned object, the method for producing semiconductor fine particles of the present invention comprises a step of producing fine particles from particles consisting of at least two elements selected from Group II to Group VI elements in a fluid of a high-pressure jet.

Since particles are made into fine particles in a fluid of a high-pressure jet having a high shearing force according to the present invention, monodisperse particles hardly showing aggregation can be conveniently produced in a simple manner even when fine particles having a minimum grain size of nanometer order or the like are produced.

The “fluid of a high-pressure jet” used in the present invention also includes “fluid of an ultrahigh-pressure jet”.

As an embodiment of the present invention, there is proposed the aforementioned method for producing semiconductor fine particles, wherein the aforementioned step comprises a step of generating a fluid of a high-pressure jet by feeding two or more solutions each containing at least one element selected from Group II to Group VI elements separately or simultaneously as a mixture to a dispersing unit in a dispersion apparatus while applying pressure to at least one of the aforementioned solutions and the mixture to produce the particles, and producing fine particles from the particles in the fluid of a high-pressure jet.

The “dispersing unit” refers to a part of an apparatus in which dispersion is substantially performed by feeding a fluid of a high-pressure jet thereto.

In this embodiment, since fine particles are simultaneously produced in the fluid of a high-pressure jet, there hardly occurs a problem of coarse particle production, which occurs, for example, when particles produced by a usual precipitation method are once isolated and then dispersed again to produce fine particles. Further, since fine particles are produced in the fluid of a high-pressure jet having a high shearing force, monodisperse particles hardly showing aggregation can be produced even when fine particles having a minimum grain size of nanometer order or the like are produced.

Further, as a preferred embodiment of the present invention, there are provided the aforementioned method for producing semiconductor fine particles, which further comprises a step of dispersing the particles prior to the aforementioned step and/or a step of dispersing the fine particles after the aforementioned step; the aforementioned method for producing semiconductor fine particles, wherein the particles are particles of compounds containing a Group II element and a Group VI element; and the aforementioned method for producing semiconductor fine particles, wherein the fluid of a high-pressure jet contains an anionic and/or nonionic surfactant.

According to the present invention, semiconductor fine particles having uniform grain sizes can be conveniently produced in a simple manner.

### BEST MODE FOR CARRYING OUT THE INVENTION

Hereafter, the production method of the present invention will be explained in detail.

The production method of the present invention comprises a step of producing fine particles from particles consisting of at least two elements selected from Group II to Group VI elements in a fluid of a high-pressure jet. The aforementioned step can be performed by using a dispersion apparatus including a mechanism capable of generating a fluid of a high-pressure jet, and it is particularly preferably performed by using a high-pressure homogenizer. The high-pressure homogenizer is composed of a high-pressure pump, an orifice unit and a dispersing unit. The reaction mixture is fed to an orifice unit while being applied with pressure by the high-pressure pump, passed through a small hole of the orifice unit and injected into the dispersing unit to be made into a fluid of a high-pressure jet. Due to collisions between the fluid of a high-pressure jets and/or collisions of the fluid jets to the wall surface of the dispersing unit etc. at high pressure, particles are produced and made finer.

The structure of the high-pressure homogenizer used in the present invention is not particularly limited, and high-pressure homogenizers having the mechanism described in U.S. Pat. No. 4,533,254, Japanese Patent Laid-open Publication (Kokai) No. 6-47264 and so forth are preferably used. Further, Gaulin Homogenizer (A. P. V Gaulin Inc.), Microfluidizer (Microfluidex Inc.), Ultimizer (Sugino Machine Ltd.) etc. are preferably used as commercially available high-pressure homogenizers. Further, such a high-pressure homogenizer having a mechanism for producing fine particles in a fluid of an ultrahigh-pressure jet as described in U.S. Pat. No. 5,720,551, which has been noted in recent years, is particularly effective for dispersion according to the present invention. As an example of a dispersing apparatus using this fluid of an ultrahigh-pressure jet, DeBEE 2000 (BEE International Ltd.) can be mentioned.

In general, in a high-pressure homogenizer, particles are produced while adjusting the pump pressure and/or the small hole diameter of orifice unit to adjust the pressure of a generated fluid of a high-pressure jet, and fine particles are produced from the produced particles by changing the shearing force applied to the particles. At this time, the desired particle size of the particles and the particle size distribution largely depend on the intensity and uniformity of the applied pressure. The reason why the exemplified DeBEE 2000 is particularly effective among high-pressure dispersion apparatuss is that it can uniformly apply high pressure.

Although the preferred range of the pressure applied to solutions fed by a high-pressure pump etc. depends on the apparatus used, it is preferably 50 MPa or higher (500 bar or higher), more preferably 100 MPa or higher (1000 bar or higher), further preferably 180 MPa or higher (1800 bar or higher), when dispersion is performed by using a high-pressure homogenizer. Further, the pressure applied to solutions etc. is preferably constant.

In the present invention, the initial velocity of the fluid of a high-pressure jet preferably corresponds to a flow rate of 300 m/sec or higher, more preferably 400 m/sec or higher, further preferably 600 m/sec or higher.

In the present invention, semiconductor fine particles having a minimum particle size of nano order, which easily form aggregations or the like when other emulsion dispersion apparatuses are used, can be efficiently produced by adjusting the flow rate of the fluid of a high-pressure jet or the like (specifically, the pressure in the pump of the high-pressure homogenizer and/or the hole size of the orifice unit), when fine particles are produced.

As an embodiment of the present invention, there can be mentioned a method for producing semiconductor fine particles, which comprises a step of producing particles by, when two or more solutions each containing at least one element selected from Group II to Group VI elements are simultaneously or separately fed into a dispersing unit, applying pressure to at least one of the aforementioned two or more solutions to generate a fluid of a high-pressure jet in the dispersing unit to produce particles, and producing fine particles from the particles in the aforementioned fluid of a high-pressure jet. This embodiment provides the production method in which two or more solutions are mixed and allowed to react to produce particles, and fine particles are simultaneously produced from the produced particles in a fluid of a high-pressure jet generated by feeding the solutions into a vessel at high pressure. In this embodiment, since the fine particles are simultaneously produced in the fluid of a high-pressure jet, there hardly occurs a problem of coarse particle production, which occurs, for example, when particles produced by a usual precipitation method are once isolated and then dispersed again to produce the fine particles. Further, since fine particles are produced in the fluid of a high-pressure jet having a high shearing force, monodisperse particles hardly showing aggregation can be produced even when fine particles having a minimum grain size of nanometer order or the like are produced.

When the aforementioned solutions are fed into the dispersing unit, pressure may be applied to all the solutions to be mixed in the dispersing unit or only a part of the solutions. For example, the solutions fed into the dispersing unit at high pressure collide to one another at high pressure and become a fluid of a high-pressure jet in the dispersing unit. Further, solutions fed into the dispersing unit at high pressure collide with wall surface or the like of the dispersing unit and become a high-pressure jet flow in the dispersing unit.

Specific embodiments using a high-pressure homogenizer will be explained below.

By using a high-pressure homogenizer having a high-pressure pump, two pairs of orifice units and a dispersing unit, each of the aforementioned two solutions is fed to each orifice unit by the high-pressure pump, passed through a small hole of the orifice unit and injected into the dispersing unit as a high-pressure jet. In the dispersing unit, the two solutions are mixed and allowed to react to produce particles, and fine particles are produced from the produced particles in the fluid of a high-pressure jet in the dispersing unit. Further, as another specific embodiment, by using a high-pressure homogenizer having a high-pressure pump, one pair of orifice units and a dispersing unit, each of the aforementioned two solutions to be mixed is fed to each orifice unit by the high-pressure pump, passed through a small hole of the orifice unit and injected into the dispersing unit as a high-pressure jet. Fine particles are produced from the produced particles in the fluid of a high-pressure jet in the dispersing unit. Further, as yet another embodiment, by using a high-pressure homogenizer having a high-pressure pump, an orifice unit and a dispersing unit, at least one of the aforementioned reaction solutions is passed through a small hole of the orifice unit to be fed as a high-pressure jet into the dispersing unit, and the other reaction solution is sucked from the bottom portion of the dispersing unit by utilizing a suction force similar to that of an aspirator. In the dispersing unit, the two of the solutions are mixed and allowed to react to produce particles, and fine particles are produced from the particles in the fluid of a high-pressure jet in the dispersing unit.

The two or more solutions are mixed in the dispersing unit to produce particles, and fine particles are produced from the particles in the fluid of a high-pressure jet. While the particles are being produced and made finer, the used solutions may be heated. The temperature for heating is not limited, but, when the solution temperature becomes too high, the solvent is evaporated and the produced particles tend to aggregate. Therefore, the temperature of the reaction solution is preferably in the range of 100° C. or lower, more preferably in the range of 50° C. The solution temperature is more preferably maintained constant in the aforementioned range.

In this embodiment, Group II to Group VI elements contained in the aforementioned solutions become elements constituting fine particles tobeproduced. For example, semiconductor fine particles of Group II-VI compounds can be produced by using a solution of a compound containing a Group II element and a solution of a compound containing a Group VI element. These solutions are solutions of a compound containing at least one of Group II to Group VI elements. The compound is not particularly limited, and various compounds can be used depending on the desired element composition of semiconductor fine particles. Examples of compounds containing a Group II element include halogenides of Group II elements (e.g., chloride), salts of various acids (e.g., sulfate, acetate, nitrate, phosphate, perchlorate, organic acid salt etc.), complex salts (e.g., acetylacetonato complex etc.) and organometallic compounds (e.g., dimethyl compounds, diethyl compounds etc.). Examples of compounds containing a Group III element include halogenides of Group III elements (e.g., chloride etc.), complex salts (e.g., acetylacetonato complex etc.) and organometallic compounds (e.g., trimethyl compounds, triethyl compounds etc.). These compounds may be either an anhydride or hydrate—Examples of compounds containing Group V and Group VI elements include alkali metal salts of each element (sodium salt, potassium salt etc.) and organic silicon compounds (trimethylsilyl salt etc.). As sulfur containing compounds among compounds containing a Group VI element, sodium thiosulfate, thiourea, thioacetamide etc. can also be used in addition to those mentioned above. Although the concentration of these raw materials used for a reaction depends on the kind of the solvent used for the reaction, it is preferably 1×10⁻⁶ to 1 mol/L, more preferably 1×10⁴ to 0.1 mol/L.

As solvent of the aforementioned solutions, either hydrophilic or hydrophobic solvent may be used, and any solvent can be used so long as a raw material compound can be dissolved therein. Examples of solvents that can be used include water, alcohols (e.g., methanol, ethanol etc.), polyhydric alcohols (e.g., ethylene glycol, diethylene glycol, polyethylene glycol etc.), glycol derivatives (e.g., ethylene glycol monomethyl ether etc.), amines (e.g., ethanolamine, hexadecylamine, hexaoctylamine, ethylenediamine, pyridine etc.), phosphine and oxides thereof (e.g., trioctylphosphine, trioctylphosphine oxide, trihexylphosphine etc.), mercapto compounds (3-mercaptotrimethylsiloxane, mercaptoethanol, 1-mercapto-2,3-propanediol etc.) and polar solvents (e.g., formamide, N,N-dimethylformamide, acetonitrile, acetone etc.) . One or more solvents may be used in combination. However, when two or more solvents are used, solvents including only either hydrophilic solvents or hydrophobic solvents are preferably used in combination considering solubility and reactivity of the raw materials. The solvent may be added with various additives beforehand.

By adding an activating agent to the aforementioned solutions beforehand, a part of metal atoms are replaced with the activating agent, and thus activated type semiconductor fine particles can be produced, in which the replacing metal functions as a light emission center. For example, by replacing a zinc atom in zinc sulfide with another metal atom, the replacing metal can be allowed to function as a light emission center. The activated type semiconductor fine particles are known to emit light unique to kind of the activating agent atom, and can emit also blue, green or red color. As the activating agent used for zinc sulfide, metals such as aluminum, manganese, copper, silver, cerium, terbium and europium are effective. These activating agents can be used in combination with fluorine, chlorine or the like as required for compensation of electric charges etc.

In the present invention, a surfactant may be added to the aforementioned solutions. Examples of surfactants that can be preferably used include fatty acid salts, alkylsulfuric acid ester salts, alkylbenzenesulfonates, alkylnaphthalenesulfonates, dialkylsulfosuccinates, alkylphosphoric acid ester salts, naphthalenesulfonic acid formalin condensates, polyoxyethylenealkylsulfuric acid ester salts and so forth as anionic surfactants; and polyoxyethylene alkyl ethers, polyoxyethylene alkyl allyl ethers, polyoxyethylene fatty acid esters, sorbitan fatty acid esters, polyoxyethylene sorbitan fatty acid esters, polyoxyethylene alkylamines, glycerine fatty acid esters, oxyethylene oxypropylene block copolymers and so forth as nonionic surfactants. One kind of these surfactants may be solely used or two or more kinds thereof may be used in combination. The surfactant may be added to a dispersion system after the production of particles.

Although the preferred range of the amount of the surfactant to be addedmay vary depending on the size of particles to be produced, it is preferably 200 parts by weight or less, more preferably 100 parts by weight or less, of the amount of completed particles. The concentration of the surfactant used is preferably 20 weight % or less, more preferably 10 weight % or less.

In the present invention, an organic binder may be added to the aforementioned solutions. If an organic binder is added, composites comprising the organic binder can be adsorbed on the surfaces of the produced particles, and hence it becomes possible to suppress aggregation of particles and prepare a dispersion having an excellent dispersing property. Examples of the organic binder that can be used include acrylic acid, methacrylic acid, esters such as methyl methacrylate, homopolymers and copolymers of vinyl monomers such as vinyl acetate and styrene, polyethylene oxide, polyvinyl alcohol, polyvinylpyrrolidone, polyacrylic acid, polyacrylamide, polymethyl methacrylate, copolymer of acrylonitrile and styrene, latex of styrene/butadiene etc., polycarbonate, fluorinated or deuterated polymethyl methacrylate, polyimide, epoxy polymer, sol/gel polymer and so forth. The polymer used as the organic binder may be either a homopolymer or a copolymer, and a photo-curing resin polymer may be used solely or mixed as required. As in the case of the surfactant, one or more kinds of these additives may be used in combination, and they may be added to a dispersion system after the production of particles, besides addition to the aforementioned solutions.

Usually, the amount of the organic binder to be added is preferably 500 parts by weight or less of the amount of completed particles. The concentration of the organic binder to be used is preferably 10 weight % or less, more preferably 5 weight % or less, of the solvent in which the organic binder is dissolved.

A method of adding a polymerizable organic compound (e.g., vinyl monomer) or a polymer thereof to the aforementioned solutions etc. and allowed to be polymerized to produce polymer composites can also be used. The polymerization can be initiated by, for example, adding a polymerization initiator such as 2,2′-azobisisobutyronitrile (AIBN) to the solutions together with a monomer or by ultraviolet irradiation. When AIBN is used, degree of polymerization can be controlled by using a radical scavenger as required. When polymerization is initiated by ultraviolet irradiation, the wavelength of the ultraviolet rays used for these compounds is preferably 300-380 nm. Polymerizable organic compounds may be added not only to the aforementioned solutions, but also to a dispersion system after the production of particles.

An adsorptive compound (dispersing agent) can also be added to the aforementioned solutions etc. to produce particles of which surfaces are modified with the adsorptive compound. As the adsorptive compound, compounds containing an adsorptive group such as —SH, —CN, —NH₂, —SO₂OH, —SOOH, —OPO(OH)₂ and —COOH are effective. Further, as the aforementioned dispersing agent, hydrophilic macromolecular compounds can be used, and examples thereof include hydroxyethylcellulose, polyvinylpyrrolidone, polyethylene glycol and so forth.

The surfaces of the particles of the present invention may be treated beforehand to obtain a good dispersion property in the aforementioned polymers, for example. For example, the thiol surface modification (M. L. Steigerwald et al., J. Am. Chem. Soc., 110, 3046, 1938), the photocatalytic reaction method (T. Hayashi et al. J. Phys. Chem., 96, 2866, 1992) and so forth can be used, but the surface treatment method is not limited to these examples.

In addition, various additives such as antistatic agent, antioxidant, UV absorber and plasticizer can be used for the aforementioned solutions etc. as required. Further, when the particles are used to label a nucleic acid, antibody, antigen or the like, the particle surfaces are particularly preferably made hydrophilic with amine, thiol or the like.

A dispersion of fine particles obtained by the aforementioned step can be further dispersed by using another known emulsion dispersion apparatus (sand grinder, colloid mill, ultrasonic dispersion apparatus etc.). This dispersion treatment can be performed when the aforementioned surfactants, organic binders, adsorbent compounds or the like are added to the dispersion.

Further, the obtained dispersion may be ripened by heating or heating under pressure. Further, particles may be separated from the dispersion to obtain powder of the particles and then they may be ripened by heating. For example, the heating favorably ripens the particles to improve crystallinity of the particles and enables control of the particle size. Although the preferred temperature range of heating of dispersion slightly varies depending on the kind of the solvent used, it is preferably 50-100° C. The temperature range of heating of particles is preferably 150-600° C., more preferably 250-500° C. Temperature of the heating is preferably maintained constant in the aforementioned ranges.

Since the dispersion of fine particles obtained by the aforementioned step contains excess cations or anions therein, the dispersion is preferably subjected to a treatment for removing these ions and then used for various purposes. The excess cations, anions etc. can be removed by precipitating the particles by centrifugation to separate them from the solution. Further, these ions can also be removed by a known ion exchange method using an ion exchange resin or an ultrafiltration membrane. Since aggregation of particles can be suppressed by removing excess cations or anions, the removal is particularly effective when the aforementioned absorptive compound or the like is not added.

As another embodiment of the present invention, there can be mentioned a method for producing semiconductor fine particles, which comprises a first step of producing particles consisting of at least two elements selected from Group II to Group VI elements, and a second step of producing fine particles from the aforementioned particles in a fluid of a high-pressure jet. In this embodiment, by subjecting the particles produced in the first step to the second step, the particles are made finer to a desired particle size. In this embodiment, since the fine particles are produced in a fluid of a high-pressure jet having a high shearing force, monodisperse particles hardly showing aggregation can be produced even when fine particles having a minimum grain size of nanometer order etc. are produced

Although the aforementioned first step is not particularly limited, the so-called precipitation method is preferred in view of productivity. As a specific embodiment of the first step utilizing the precipitation method, there can be mentioned a step of mixing two or more kinds of the aforementioned solutions of a compound containing at least one of Group II to Group VI elements with stirring to obtain particles consisting of at least two elements selected from Group II to Group VI elements as precipitates. This step can be performed by using a known emulsion dispersion apparatus. The fine particles of the Group II to Group VI compounds produced in the liquid phase in the first step can be separated from the liquid phase and then used for the second step after they are subjected to washing or the like as desired or as they are. The solutions can be added with the aforementioned activating agent, surfactant, organic binder, adsorptive compound and so forth.

In the second step, fine particles are produced from the produced particles in a fluid of a high-pressure jet. The second step can be performed by using a high-pressure homogenizer. For example, a dispersion of the particles obtained in the first step can be applied with pressure by using pressure pump, fed to an orifice unit, passed through a small hole of the orifice unit and injected into a dispersing unit as a fluid of a high-pressure jet to make the particles in the dispersion finer. During the process of the second step or after the completion of the second step, the aforementioned surfactant, organic binder, adsorptive compound or the like can be added.

After the second step, a dispersing treatment and/or ripening treatment can also be further performed by using another emulsion dispersion apparatus. Further, as described above, after the second step, the dispersion can be subjected to centrifugation or the like to remove excess cations and anions, and then used for various purposes.

By the production method of the present invention, there can be obtained, for example, such particles as described in J. Am. Chem. Soc. 1993, 115, 8706-8715, “Synthesis and Characterization of Nearly Monodisperse CdE (E=S, Se, Te) Semiconductor Nanocrystallites”; and Hyomen Kagaku (Surface Chemistry), 22, 5, “Light-Emitting Mechanism and Local Structure Analysis of Organic/Inorganic Composite Type ZnS: Mn Nanocrystal Fluorescent Substance”.

Semiconductor fine particles produced by the method of the present invention can be used for the optical switching element described in Japanese Patent Laid-open Publication No. 2000-321607, the optical memory element using interference of multiple scattered light described in Japanese Patent Laid-open Publication No. 2000-99986, the optical memory element described in Japanese Patent Laid-open Publication No. 2000-81682, the EL element described in Japanese Patent Laid-open Publication No. 2001-18677, the optical recording medium described in Japanese Patent Laid-open Publication No. 2000-178726, the photoelectric conversion elements described in Japanese Patent Laid-open Publication Nos. 07-95774 and 07-75162, the diagnosis element described in British Patent No. 2342651, the analyzing element described in U.S. Pat. No. 5,990,479 and so forth.

For the aforementioned purposes, the particles can be supplied in the form of a thin film formed from a dispersion obtained by dispersing the obtained semiconductor fine particles in a solvent with a binder etc. In order to form a thin film, there can be used application type coating methods such as a roller coating method, dip coating method etc.; metering type coating methods such as an air knife coating method, blade coating method etc.; and as methods enabling application of the application type and metering type coating methods to the same region, the wire bar coating method disclosed in Japanese Patent Publication (Kokoku) No. 58-4589, the slide hopper method, extrusion coating method, curtain coating method etc. described in U.S. Pat. Nos. 2,681,294, 2,761,419, 2,761,791 etc. Further, in order to form a thin film, a general-purpose machine for performing spin coating method or spray coating method is also preferably used. Further, in order to form a thin film, there are also preferably utilized wet printing methods including the three major printing methods of relief printing, offset printing and gravure printing, intaglio printing, rubber plate printing, screen printing and so forth. From these methods, a preferred film forming method can be selected depending on viscosity of the dispersion and wet thickness of thin film.

Viscosity of the dispersion of semiconductor fine particles largely depends on kind and dispersion property of semiconductor fine particles to be produced and kind of a solvent to be used, additives (surfactant, binder etc.) to be used and so forth. For a high viscosity dispersion (e.g., 0.1-500 Pass (0.1-500 Poise)), the extrusion method, casting method, screen printing method or the like is preferably used. For a low viscosity dispersion (e.g , 0.1 Pass or lower (0.1 Poise or lower)), the slide hopper method, wire bar method or spin coating method is preferably used, and a uniform film can be formed by such a method. When the coating amount exceeds a certain level, the coating can be performed by the extrusion coating method even with a low viscosity dispersion. Thus, an appropriate wet film forming method may be selected depending on the viscosity of coating dispersion, coating amount, support, coating rate etc.

The aforementioned thin film having a laminate structure can be used for the aforementioned purposes. For example, there can be mentioned a thin film formed by applying dispersions each containing semiconductor fine particles having a different grain size in multiple layers, a thin film formed by applying dispersions each containing semiconductor fine particles of different kind of compound (or different binder, additive etc.) in multiple layers and so forth. It is also effective to apply the same dispersion in multiple layers when a film thickness enough for obtaining sufficient performances cannot be obtained by a single coating. The extrusion coating method and the slide hopper method are suitable for multilayer coating. Further, when multilayer coating is performed, multiple layers may be simultaneously applied, or several to several tens of layers may be successively applied. Further, when multiple layers are successively applied, the screen printing method may also be preferably used.

### EXAMPLES

The present invention will be more specifically explained with reference to the following examples. Materials, reagents, proportions, procedures and so forth mentioned in the following examples can be appropriately changed unless such changes depart from the spirit of the present invention. Accordingly, the scope of the present invention is not limited to these specific examples.

### Preparation of Dispersion A

A dispersion of particles was prepared by using a high-pressure homogenizer “DeBEE 2000” (BEE International Ltd.). The DeBEE 2000 is constituted from a high-pressure hydraulic pump, an orifice unit having a small hole anda dispersing unit (cylindrical cell). The solutions were fed from the high-pressure hydraulic pump to the orifice unit, passed through the small hole of the orifice unit and injected into the dispersing unit. In this example, Solution (i) mentioned in the following Table 1 was fed from the high-pressure hydraulic pump to the orifice unit at 2100 bar, passed through the small hole of the orifice unit and injected into the cylindrical cell. At the same time, Solution (iii) mentioned in Table 1 was injected into the cylindrical cell from a small hole of the bottom portion of the cylindrical cell by utilizing a suction force similar to that of an aspirator to prepare Dispersion A.

### Preparation of Dispersion B

Dispersion B was prepared in the same manner as in the preparation of Dispersion A except that Solution (ii) mentioned in Table 1 was used instead of Solution (i).

### Preparation of Dispersion C

Solution (i) mentioned in Table 1 was placed in a beaker and added with Solution (iii) mentioned in Table 1 at a rate of 200 mL/min with stirring by a stirrer. This dispersion was centrifuged at 8000 rpm for 15 minutes. The precipitated particles were collected by filtration, washed with water and methanol and dried at 45° C. for 24 hours to obtain particles. The obtained particles (0.3 g), water (75 g) and zirconia beads (f 0.05 mm, 450 g) were placed in a dispersion vessel for a sand grinder mill and dispersed at 1800 rpm at 2 hours. The zirconia beads were removed by using filter cloth to obtain a dispersion. This dispersion was dispersed by using DeBEE 2000 under the same conditions as in the preparation of Dispersion A to obtain Dispersion C.

### Preparation of Dispersion D

Solution (i) mentioned in Table 1 was placed in a beaker and added with Solution (iii) mentioned in Table 1 at a rate of 200 mL/min with stirring by a stirrer to prepare Dispersion D.

### Preparation of Dispersion E

Dispersion E was prepared in the same manner as in the preparation of Dispersion D except that Solution (ii) mentioned in Table 1 was used instead of Solution (i).

### Preparation of Dispersion F

Solution (i) mentioned in Table 1 was placed in a beaker and added with Solution (iii) mentioned in Table 1 at a rate of 200 mL/min with stirring by a stirrer. This dispersion was centrifuged at 8000 rpm for 15 minutes. The precipitated particles were washed with water and methanol and dried at 45° C. for 24 hours to obtain particles. The obtained particles (0.3 g), water (72 g) and zirconia beads (f 0.05 mm, 450 g) were placed in a dispersion vessel for a sand grinder mill and dispersed at 1800 rpm at 2 hours. The zirconia beads were removed by using filter cloth to obtain Dispersion F.

TABLE 1

| Compound | (i) | (ii) | (iii) |
|---|---|---|---|
| Zinc acetate dihydrate | 22 g | 22 g | — |
| Sodium sulfide nonahydrate | — | — | 24.7 g |
| Sodium dodecylbeuzenesulfonate | — | — | 7 g |
| Acrylic acid | — | 14.4 g | — |
| Water | 2000 ml | 2000 ml | 1000 ml |
| Methanol | — | — | 1000 ml |

(Evaluation of particle size and size distribution)

The particles of obtained Dispersions A to F were photographed by a transmission microscope, and the average grain size and the size distribution of about 150 particles were measured. The size distribution is shown in Table 2 as coefficient of variation together with the particle size.

TABLE 2

| Sample | Average particle size | Standard deviation | Note |
|---|---|---|---|
| A | 3.4 | 0.65 | Invention |
| B | 3.4 | 0.62 | Invention |
| C | 3.1 | 0.64 | Invention |
| D | 3.6 | 1.12 | Comparative |
| E | 3.4 | 1.08 | Comparative |
| F | 3.3 | 1.09 | Comparative |

Unit of average particle size: nm

Unit of average particle size: nm

What is claimed is:

1. A method for producing semiconductor fine particles, which comprises a step of producing fine particles from particles consisting of at least two elements selected from Group II to Group VI elements in a fluid of a high-pressure jet.

2. The method for producing semiconductor fine particles according to claim 1, wherein the step comprises producing the particles by, when two or more solutions each containing at least one element selected from Group II to Group VI elements are simultaneously or separately fed into a vessel, applying pressure to at least one of the two or more solutions to form a fluid of a high-pressure jet in the vessel and producing fine particles from the particles in the fluid of a high-pressure jet.

3. The method for producing semiconductor fine particles according to claim 1, which further comprises dispersing the particles before the step and/or dispersing the fine particles after the step.

4. The method for producing semiconductor fine particles according to claim 1, wherein the particles comprise a Group II element and a Group VI element.

5. The method for producing semiconductor fine particles according to claim 1, wherein the fluid of a high-pressure jet contains an anionic and/or nonionic surfactant.
